(19) United States
(12) Patent Application Publication
(10) Pub. No.: US 2009/0027858 A1
(43) Pub. Date: Jan. 29, 2009

(54) HEAT DISSIPATING DEVICE ASSEMBLY

(75) Inventors: CHENG-TIEN LAI, Tu-Cheng (TW); JIN-SONG FENG, Shenzhen (CN); SONG-SHUI LIU, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 11/782,459

(22) Filed: Jul. 24, 2007

(51) Int. Cl. H05K 7/20

(52) U.S. Cl. 361/709; 165/185; 165/80.2

(57) ABSTRACT

A heat dissipating device assembly for dissipating heat generated by an electronic component (32) mounted on a printed circuit board (30) is disclosed. The heat dissipating device assembly includes a back plate (26) mounted below the printed circuit board, a retention module (22) secured on the printed circuit board, a heat sink (10) disposed on the retention module for contacting the electronic component, and a pair of wire clips (24) pivotably attached to two opposite walls (222) of the retention module. The pair of clips produce symmetrical pressure acting on two lateral sides of the heat sink, thus holding the heat sink in reliable contact with the electronic component.

### BACKGROUND OF THE INVENTION

1. Field of the Invention

The present invention relates to a heat dissipating device assembly, and more particularly to a heat dissipating device assembly incorporating a locking device for securing a heat sink to a printed circuit board conveniently.

2. Description of Related Art

As computer technology continues to advance, electronic components such as central processing units (CPUs) of computers are made to provide faster operational speed and greater functional capabilities. When a CPU operates at a high speed in a computer enclosure, its temperature increases greatly and dramatically. It is desirable to dissipate the generated heat quickly, for example, by using a heat sink attached to the CPU in the enclosure. This allows the CPU and other electronic components in the enclosure to function within their normal operating temperature ranges, thereby assuring the quality of data management, storage and transfer. Generally, a locking device is required for mounting the heat sink to the CPU.

U.S. Pat. No. 6,339,533 shows a heat dissipating device, which comprises a heat sink and a locking device. The heat sink further comprises a base and a plurality of fins extending from the base. A pair of shoulders are formed on two lateral sides of the base. The locking device comprises a retention module and a pair of clips. Each clip has a pair of locking feet defining locking openings therein and slots adjacent to the locking openings. Four barbs are formed at four corners of the retention module. In assembly, the retention module is mounted on a printed circuit board with the heat sink placed on an electronic component. The clips are disposed on the shoulders of the heat sink in a manner such that the locking opening of one locking foot of each clip engages with corresponding barb of the retention module. Tool is inserted into the slot of other locking foot of each clip to pivot the other locking foot for engaging other locking opening with the corresponding barb of the retention module, thereby securing the heat sink to the electronic component. However, it is inconvenient to use tool in assembly.

What is needed, therefore, is heat dissipating device which can overcome the above-mentioned disadvantages.

### SUMMARY OF THE INVENTION

A heat dissipating device assembly is disclosed for dissipating heat generated by an electronic component mounted on a printed circuit board. The heat dissipating device assembly includes a back plate mounted below the printed circuit board, a retention module secured on the printed circuit board, a heat sink disposed on the retention module for contacting the electronic component, and a pair of wire clips pivotably attached to two opposite walls of the retention module. The pair of clips produce symmetrical pressure acting on two opposite lateral sides of the heat sink, thus holding the heat sink in reliable contact with the electronic component.

Other advantages and novel features of the present invention will become more apparent from the following detailed description when taken in conjunction with the accompanying drawings, in which:

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an exploded, isometric view of a heat dissipating device assembly with a printed circuit board having an electronic component mounted thereon in accordance with a preferred embodiment of the present invention;

FIG. 2 is an enlarged, exploded view of a heat sink of FIG. 1;

FIG. 3 is an enlarged, exploded view of a retention module and a pair of clips of FIG. 1;

FIG. 4 is an assembled view of FIG. 3;

FIG. 5 is an assembled view of FIG. 1 with the pair of clips located in a released position; and

FIG. 6 is an assembled view of FIG. 1 with the pair of clips located in a locked position.

### DETAILED DESCRIPTION OF THE INVENTION

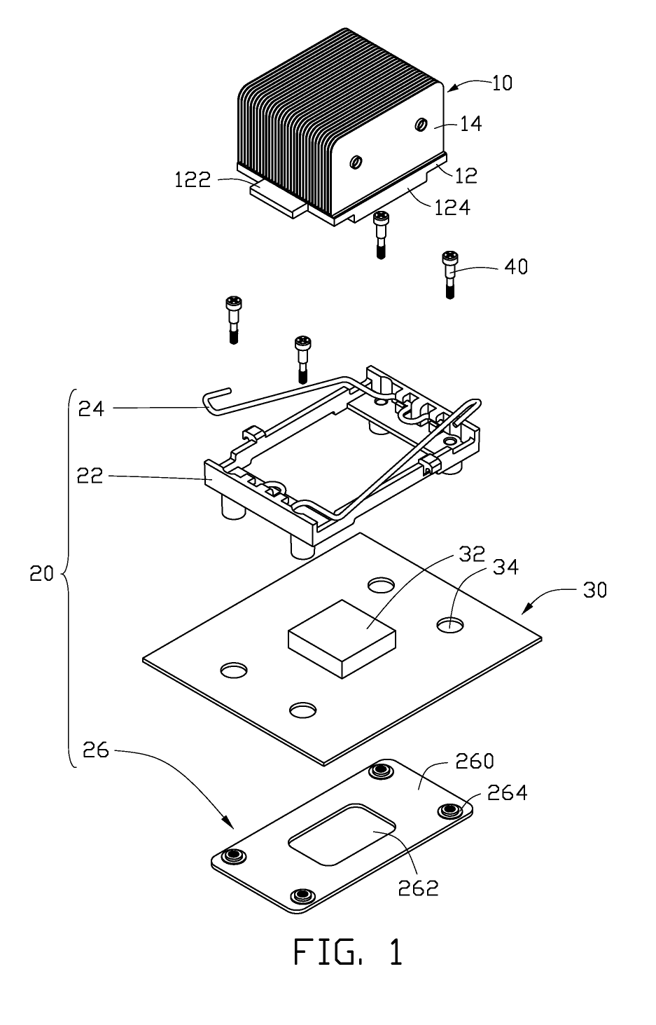

Referring to FIG. 1, a heat dissipating device assembly in accordance with a preferred embodiment of the present invention comprises a heat sink 10 for dissipating heat generated by an electronic component 32 that is mounted on a printed circuit board 30, and a locking device assembly 20 for securing the heat sink 10 on the electronic component 32. The printed circuit board 30 defines four through holes 34 therein around the electronic component 32.

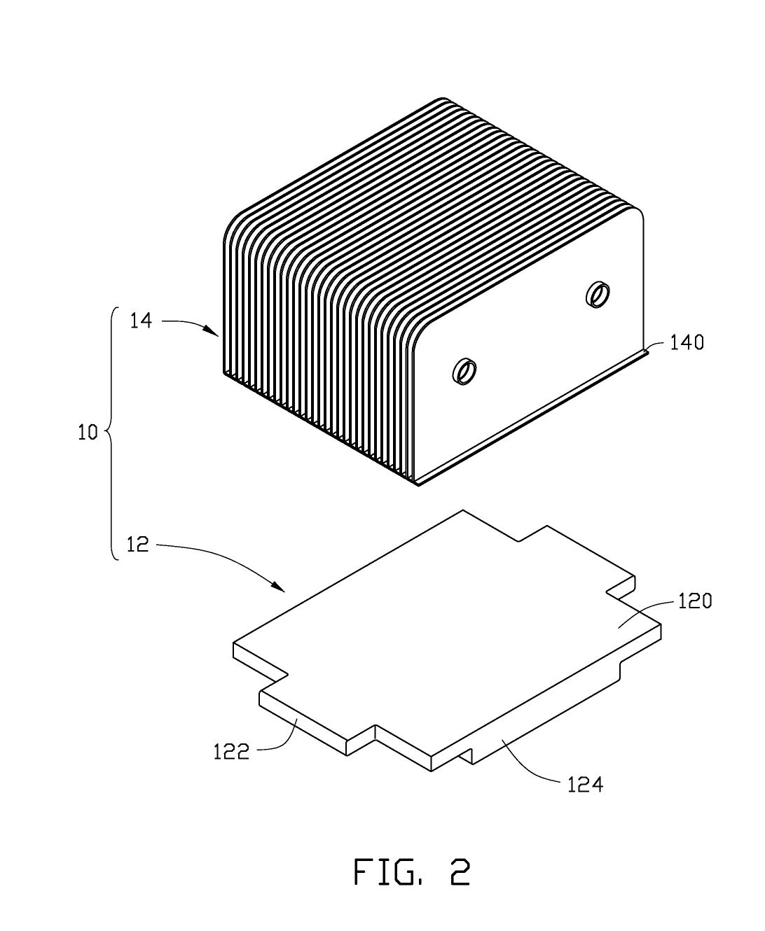

Referring to FIGS. 1-2, the heat sink 10 comprises a base 12 and a plurality of fins 14 attached to the base 12. The base 12 comprises a rectangular plate 120. A rectangular protrusion 124 projects downwardly and vertically from a bottom face of the plate 120 and in a central area of the base 12 for contacting the electronic component 32, wherein the protrusion 124 has a smaller area than that of the plate 120. A pair of border portions 122 are formed horizontally and outwardly at two opposite lateral sides of the plate 120. A plurality of evenly spaced fins 14 is arranged on a top face of the plate 120 in a manner such that each fin 14 forms a flange 140 at a bottom portion thereof for contacting with the base 12 by soldering, thereby increasing contact surface between the base 12 and the fins 14. The flanges 140 of the fins 14 form a bottom face having an area identical to the plate 120 of the base 12 with the two border portions 122 of the base 12 extending outside reach of the fins 14.

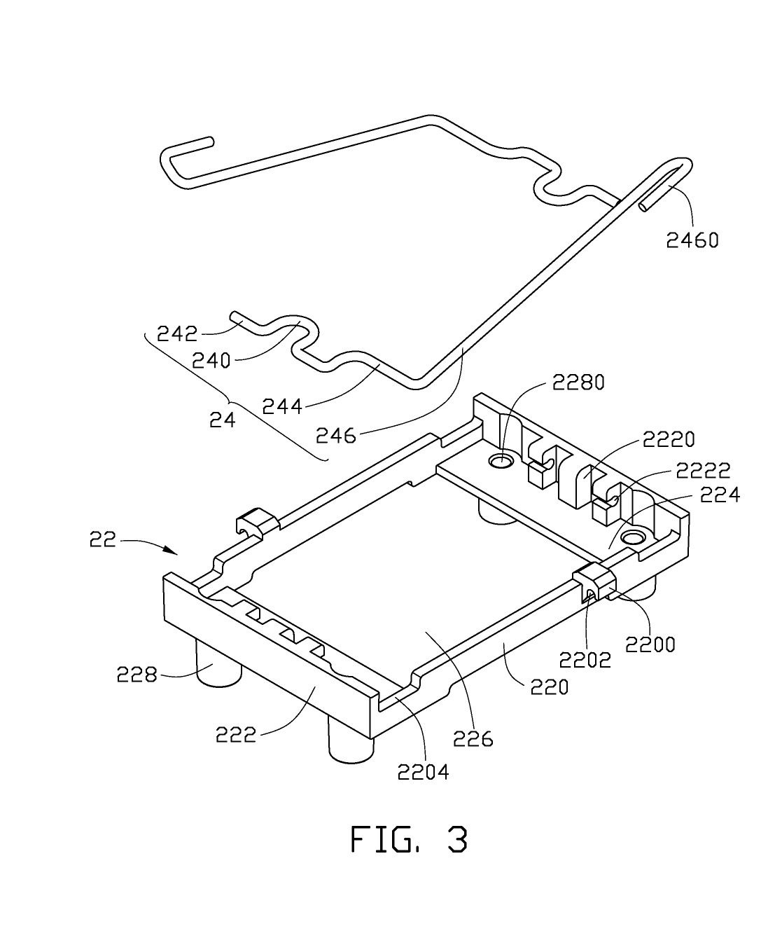

Referring to FIGS. 1 and 3, the locking device assembly 20 comprises a retention module 22, a back plate 26 mounted below the retention module 22 and the printed circuit board 30, and a pair of identical wire clips 24 attached to the retention module 22. The retention module 22 is disposed on the printed circuit board 30 and comprises four walls 220, 222 to construct a rectangular configuration therefore. A pair of abutting strips 224 extend inwardly and perpendicularly from bottom portions of inner sides of two opposite walls 222 respectively with two opposite lateral portions of the abutting strips 224 attached to other two opposite walls 220. The abutting strips 224 and the other two opposite walls 220 cooperatively enclose a rectangular opening 226 in a central area of the retention module 22. The opening 226 has an area larger than that of the protrusion 124 of the heat sink 10 for allowing the protrusion 124 to extend therethrough. Three bulges 2220 project inwardly and vertically from the inner side of each wall 222 with bottom portions thereof contacting a top face of a corresponding abutting strip 224, wherein a pair of grooves 2222 are defined in two lateral bulges 2220 along an elongated direction of the wall 222. Each wall 220 defines two identical cutouts 2204 in a top portion of two lateral sides thereof. A block 2200 with a retaining slot 2202 defined in a bottom portion thereof is formed outwardly and horizontally on an outer periphery of each wall 220 and adjacent to the corresponding abutting strip 224. Four hollow locking feet 228 extend downwardly and perpendicularly from bottom faces of the abutting strips 224 at four corners of the retention module 22 corresponding to the four through holes 36 of the printed circuit board 30. Each locking foot 228 defines a through hole 2280 therein for providing passages of screws 40 to attach the retention module 22 to the printed circuit board 30.

The pair of clips 24 pivotably engage with the two opposite walls 222 of the retention module 22 respectively. Each clip 24 is made by bending a metal wire and comprises a pressing section 240, a pair of positioning sections 242, a connecting section 244, and a locking section 246. The pressing section 240 has an arced shape with the pair of positioning sections 242 extending outwardly and horizontally from two free ends of the pressing section 240. The connecting section 244 extends outwardly from a distal end of one positioning section 242 in a manner such that the pressing section 240, the positioning sections 242, and the connecting section 244 are placed in a common plane. The locking section 246 is formed slantwise and upwardly at a free end of the connecting section 244, to thereby have an acute angel between the locking section 246 and the plane defined by the pressing section 240. A free end of the locking section 246 opposing to the connecting section 244 is bent to form a handle 2460 for facilitating an operation of the clip 24.

Referring to FIG. 1 again, the back plate 26 is mounted below the printed circuit board 30 and comprises a rectangular body 260. A rectangular hole 262 is defined in a central area of the body 260. Four screw supports 264 are formed on a top face of the body 260 at four corners of the back plate 26 in such a manner that the screw supports 264 surround the hole 262 of the back plate 26 and correspond to the four through holes 34 of the printed circuit board 30.

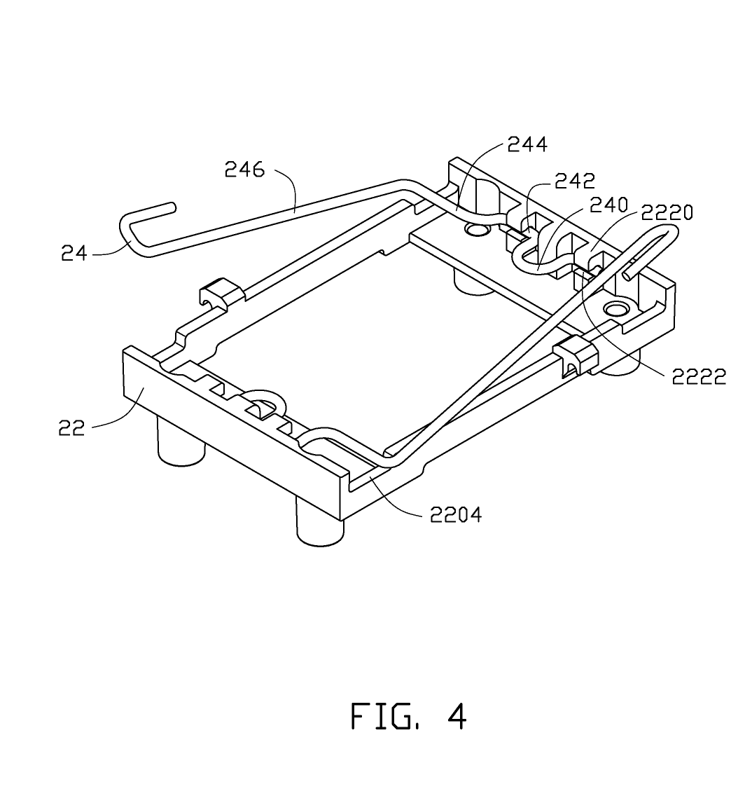

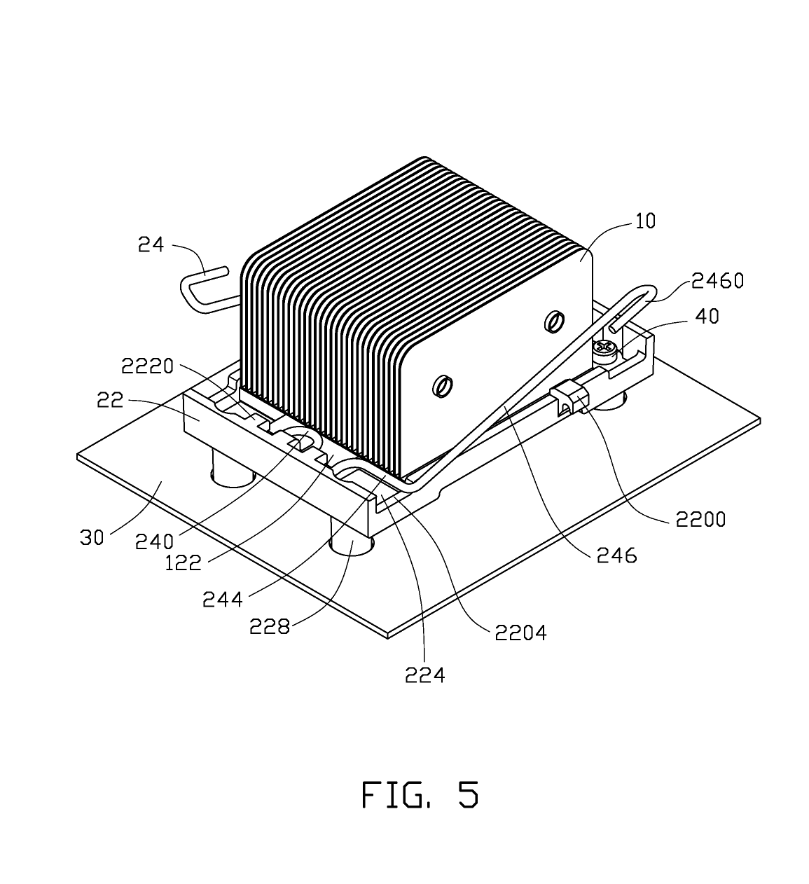

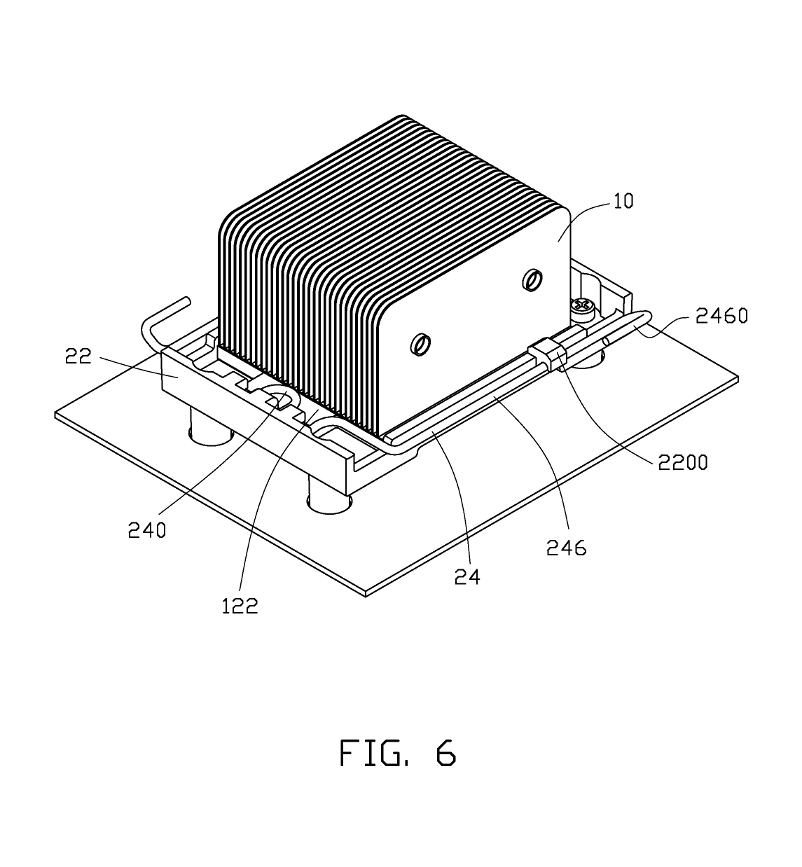

As shown in FIGS. 1-5, in assembly, the retention module 22 is disposed on the printed circuit board 30 with four locking feet 228 extending through corresponding through holes 34 of the printed circuit board 30. The back plate 26 is mounted below the printed circuit board 30 with four screw supports 264 corresponding to the through holes 34 of the printed circuit board 30 in a manner such that the screws 40 extend through the through holes 2280, 34 of the retention module 22 and the printed circuit board 30 to threadedly engage with corresponding screw supports 264 of the back plate 26, thus securing the back plate 26 to the printed circuit board 30 with the retention module 22. The heat sink 10 is placed on the retention module 22, wherein the protrusion 124 projects downwardly through the opening 226 of the retention module 22 to contact the electronic component 32, and the border portions 122 are supported by the corresponding abutting strips 224 of the retention module 22. The two positioning sections 242 of each clip 24 are engaged in corresponding grooves 2222 of the bulges 2220 of the retention module 22 with the pressing section 240 of the clip 24 spanning across the middle bulge 2220 of the retention module 22 for sandwiching the border portion 122 of the heat sink 10 with the abutting strip 224 of the retention module 22. The connecting section 244 of each clip 24 extends through corresponding cutout 2204 of the retention module 22 and the locking section 246 is located above the retention module 22 to hold the clip 24 in a release position. Referring to FIG. 6, the handles 2460 of the clips 24 are pressed downwardly until the locking portions 246 of the clips 24 reach and are retained in corresponding retaining slots 2202 of the blocks 2200, thus resiliently deforming the clips 24. At the locked position of FIG. 6, the pressing sections 240 of the clips 24 perform downward pressures acting on the border portions 122 of the heat sink 10. Thus, the heat sink 10 is firmly secured to the electronic component 32 and the retention module 22 without using a tool.

Since the pressures engendered by the two pressing sections 240 of the clips 24 act on two opposite lateral sides of the heat sink 10, a balance of force acting on the heat sink 10 is obtained for preventing the heat sink 10 from slanting in respect to the electronic component 32; thus, the locking device assembly 20 in accordance with the present invention can hold the heat sink 10 to intimately contact the electronic component 32 reliably and stably, without the possibility of causing damage to the electronic component 32.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipating device assembly adapted for dissipating heat generated by an electronic component mounted on a printed circuit board, the heat dissipating device comprising:
a heat sink comprising a base adapted for contacting the electronic component, and a plurality of fins extending from the base;
a locking device assembly comprising:
a retention module adapted for being mounted on the printed circuit board and surrounding the electronic component, the retention module comprising two opposite walls and other two opposite walls connected with each other;
a back plate adapted for being secured below the printed circuit board and engaging with the retention module; and
a pair of wire clips being pivotably attached to inner sides of the two opposite walls of the retention module, the clips comprising a pair of pressing sections for abutting against two opposite lateral sides of the base of the heat sink, wherein when the heat sink is placed on the retention module, the clips are pivoted to locked positions in which the pressing sections of the clips press the two opposite lateral sides of the base of the heat sink towards the electronic component, for having a reliable contact between the heat sink and the electronic component in a balance manner.

2. The heat dissipating device assembly of claim 1, wherein the base of the heat sink comprises a protrusion projecting downwardly therefrom, and a pair of border portions extending outwardly from the two opposite lateral sides thereof, the protrusion is adapted for contacting the electronic component.

3. The heat dissipating device assembly of claim 2, wherein a pair of abutting strips extend inwardly from the inner sides of the two opposite walls of the retention module for supporting the border portions of the heat sink.

4. The heat dissipating device assembly of claim 3, wherein the abutting strips and the other two opposite walls of the retention module cooperatively define an opening for allowing the protrusion of the heat sink to extend therethrough.

5. The heat dissipating device assembly of claim 3, wherein a plurality of bulges are formed inwardly at the inner sides of the two opposite walls of the retention module above the abutting strips, and at least two bulges located at two sides of the bulges at one of the two opposite walls define two grooves therein respectively.

6. The heat dissipating device assembly of claim 5, wherein a pair of blocks are formed outwardly on outer peripheries of the other two opposite walls of the retention module in a manner such that each of the blocks defines a retaining slot therein.

7. The heat dissipating device assembly of claim 6, wherein the pressing section of each of the clips has an arced shaped configuration, the pressing section of the each of the clips and corresponding abutting strip of the retention module sandwich a corresponding border portion of the heat sink therebetween.

8. The heat dissipating device assembly of claim 6, wherein the each of the clips further comprises a pair of positioning sections extending from free ends of the pressing section adapted for being engaged in corresponding grooves of the bulges of the retention module.

9. The heat dissipating device assembly of claim 8, wherein the each of the clips further comprises a locking section extending from a distal end of one positioning section for being retained in a corresponding retaining slot of one of the blocks of the retention module.

10. The heat dissipating device assembly of claim 9, wherein the positioning sections and the pressing section of the each of the clips are located in a common plane, and the locking section of the each of the clips defines an acute angle with the plane.

11. A locking device assembly for securing a heat sink to a printed circuit board, the locking device assembly comprising:
a retention module adapted for being secured on the printed circuit board, comprising two opposite walls and other two opposite walls connecting with each other, a pair of abutting strips extending inwardly from the two opposite walls thereof to define an opening together with the other two opposite walls thereof, a plurality of bulges projecting inwardly from the two opposite walls;
a back plate adapted for being mounted below the printed circuit board to sandwich the printed circuit board between the back plate and the retention module; and
a pair of clips comprising a pair of first portions pivotably engaging with corresponding bulges of the two opposite walls of the retention module, and a pair of second portions for being attached to the other two opposite walls of the retention module, respectively, the clips being adapted for providing symmetrical pressure acting on two lateral sides of the heat sink, thus holding the heat sink in reliable contact with the electronic component.

12. The locking device assembly of claim 1, wherein the bulges are located above the abutting strips of the retention module with the bulges located at two sides of corresponding one of the two opposite walls of the retention module defining grooves therein respectively.

13. The locking device assembly of claim 12, wherein each of the other two opposite walls of the retention module defines a pair of cutouts in a top portion of two lateral sides thereof.

14. The locking device assembly of claim 13, wherein the each of the other two opposite walls of the retention module outwardly forms a block between the cutouts thereof, the block defining a retaining slot therein.

15. The locking device assembly of claim 14, wherein each of the first portions of the clips comprises an arced pressing section adapted for abutting against the heat sink, and a pair of positioning sections extending outwardly from free ends of the pressing section, the positioning sections are engaged in corresponding grooves of the bulges of the retention module.

16. The locking device assembly of claim 15, wherein said each of the first portions of the each of the clips further comprises a connecting section extending outwardly from a distal end of one of the positioning sections in a manner such that the connecting section extends through corresponding cutout of the retention module.

17. The locking device assembly of claim 16, wherein each of the second portion of the clips comprises a locking section formed at a free end of the connecting section for being retained in a corresponding retaining slot of the block of the retention module, and said each of the first portions and a corresponding one of the second portions define an acute angle therebetween.
